(19) United States
(12) Patent Application Publication
(10) Pub. No.: US 2002/0087927 A1
(43) Pub. Date: Jul. 4, 2002

(54) Method for testing integrated circuits

(76) Inventors: Norbert Felber, Zuerich (CH); Hubert Kaeslin, Schwerzenbach (CH)

Correspondence Address: U.S. Philips Corporation, 580 White Plains Road, Tarrytown, NY, 10591, US

(21) Appl. No.: 10/003,673

(22) Filed: Nov. 2, 2001

(30) Foreign Application Priority Data
Nov. 6, 2000 (EP) 00124076.1

(51) Int. Cl. G01R 31/28

(52) U.S. Cl. 714/724

(57) ABSTRACT

The method according to the present invention relates to the detection of fabrication defects in static CMOS circuits. An integrated circuit, for instance, having a gate (12, 13) additionally includes two sleep transistors (14, 15) and two pull transistors (16, 17) of regular threshold and low leakage. The sleep transistors are used to break up the gate into two parts (12; 13) for allowing a pair of response sequences. The two responses are either checked for consistency or compared against a predetermined expected response sequence. The usage of the pull transistors is as passive loads such as to enable pseudo NMOS and pseudo PMOS operation. One of the advantages of the method according to the invention, is that it is insensitive to MOSFET leakage currents.

The present invention relates to a method for testing integrated circuits and integrated circuits including means for fabrication testing.

In last years, circuit designs for quiescent current fault testing, commonly referred to as IDDQ (I_{DD}=power supply current; Q=quiescent) testing, have been proposed. Such IDDQ testing has been a very effective method for detecting fabrication defects in static CMOS circuits. However, said known conventional fault detection fails to detect faults in deep submicron CMOS technologies, because the fault-induced short-circuit currents are exposed to masking by the superimposed MOSFET leakage currents (MOSFET stands for metal-oxide-semiconductor field-effect transistor). This phenomenon is prone to become more serious with every process generation as the overall leakage current increases with growing transistor count and diminishing MOSFET threshold voltages Vₜₕₙ and Vₜₕₚ. Difficulties arise from the fact that the scaling of threshold voltages is necessary to maintain current and speed levels when the supply voltage V_{dd} is being lowered, and V_{dd}, in turn, must be reduced to stay clear of destructive electrical fields when geometrical dimensions are shrunk from one process generation to the next. As a result, traditional IDDQ testing is no longer possible below a feature size of approximately 0.25 μm.

Therefore, an object of the present invention is to provide an improved method for testing integrated circuits (ICs) and to provide an integrated circuit including special means for uncovering fabrication defects. The method according to the invention will be referred to as IRRQ testing, wherein the acronym IRRQ stands for “Inherently Redundant logic Repeated Qualification”.

Integrated logic circuits including test controlled impedance element(s) for impedance fault detection are addressed in U.S. Pat. No. 5,383,194. The test controlled impedance element(s) allow to determine whether the circuit's digital output signal is outside a predetermined range.

A method for testing integrated circuits having a number of field-effect transistors (FETs) of low threshold voltages is proposed. According to this method at least one circuit cell is tested. In order to do so, this circuit cell is temporarily separated into two independent cell networks. A first response sequence is obtained for the first of the two independent cell networks and/or a second response sequence is obtained for the second of the two independent cell networks. Then, it is determined whether a defect is detected in said circuit cell. This can either be done by detecting an inconsistency between either of said two sequences of actual responses and a sequence of expected responses, or by directly comparing the sequence of actual responses of the first cell network with the sequence of actual responses of the second cell network.

According to the present invention, an integrated circuit is provided which includes means for fabrication testing. The integrated circuit comprises one, a subset, or all of its circuit cells that include means such as to electrically separate each circuit cell into a first cell network and a second cell network, and at least one output giving a first response sequence for the first of the two independent cell networks and/or a second response sequence for the second of the two independent cell networks.

Other embodiments of the invention are characterized by the features presented in the dependent claims.

According to one aspect of the present invention a pair of high threshold voltage transistors is employed to break a CMOS gate into PMOS (1st cell network) and an NMOS (2nd cell network) part, each of which can subsequently be tested separately from the other.

One of the advantages of the method according to the invention is that it is less sensitive to MOSFET leakage currents.

It is another advantage of the present scheme that the benefits of testability and low standby current from a common network structure are being combined.

Another advantage of said method is, that it is immaterial whether the used unscaled and/or scaled threshold MOSFETs are being manufactured as such, or whether they are obtained electrically after fabrication, e.g., by way of back-biasing, overdriving or precharging of a floating gate.

The present scheme can be used to detect defects in CMOS (complementary metal oxide semiconductor) and BiCMOS (bipolar devices combined with CMOS subcircuits on a single chip), for example.

The present IRRQ testing scheme can be advantageously used in future devices where off-state leakage currents are such that they would mask defect induced currents through the circuit and so render the conventional IDDQ analysis inconclusive.

These and other aspects of the invention will be apparent from and elucidated with reference to the embodiment(s) described hereinafter.

For a more complete description of the present invention and for further objects and advantages thereof, reference is made to the following description, taken in conjunction with the accompanying drawings, in which:

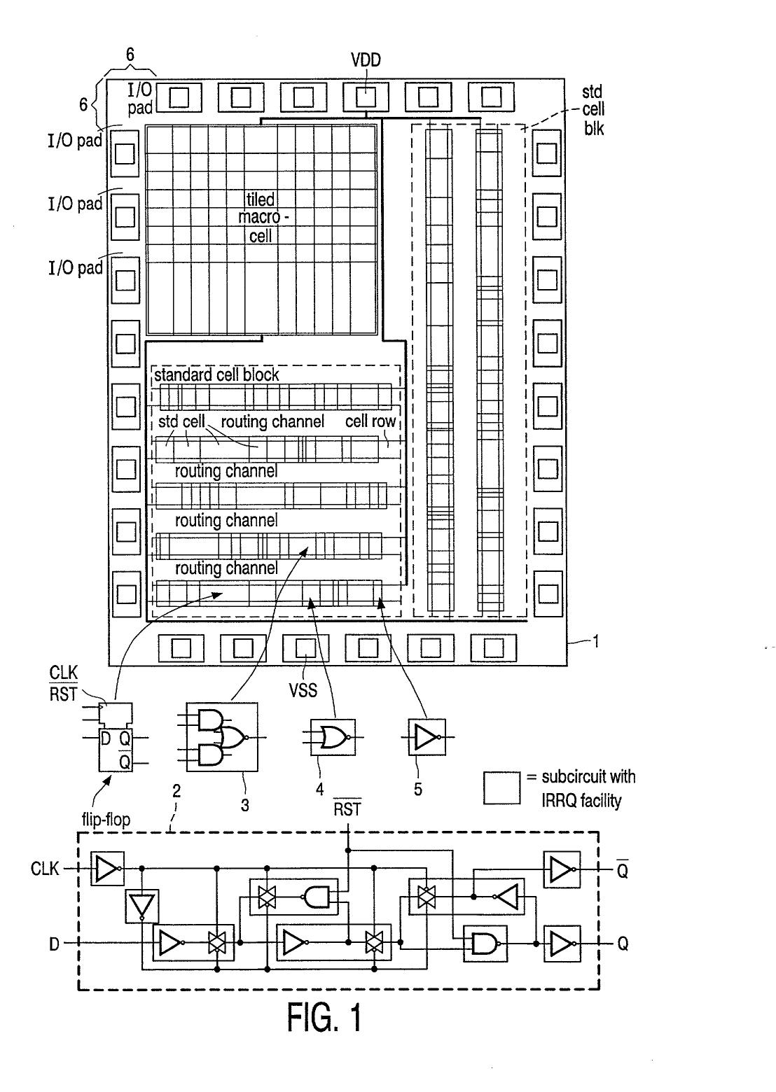

FIG. 1 shows a simplified illustration of a digital IC with a subset of IRRQ circuits highlighted;

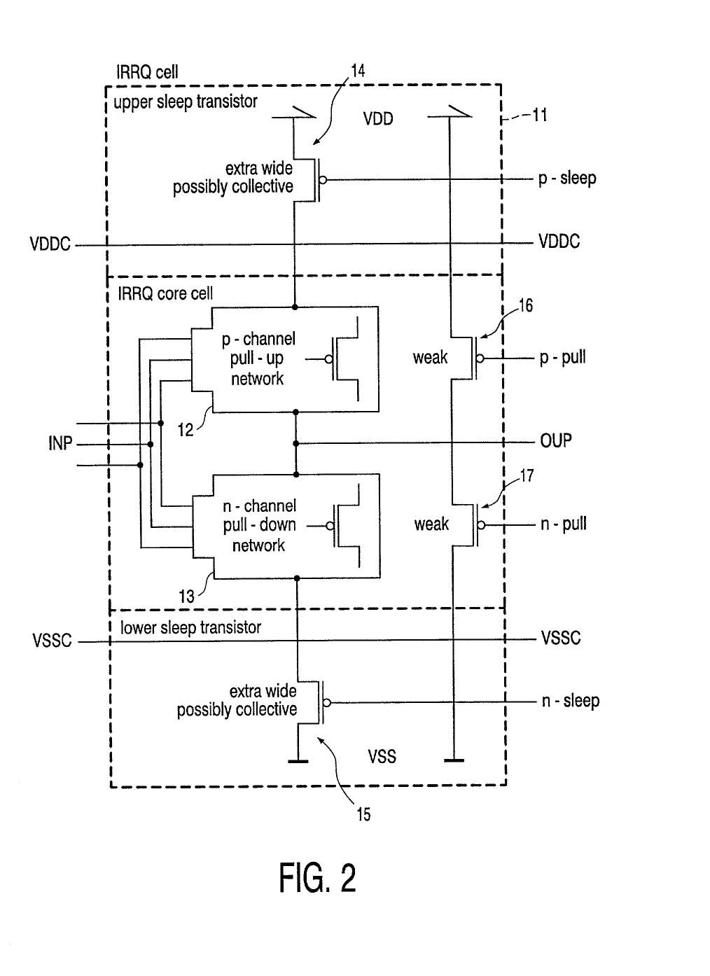

FIG. 2 is a schematic illustration of the model structure of a general arrangement of an IRRQ gate implemented in CMOS technology;

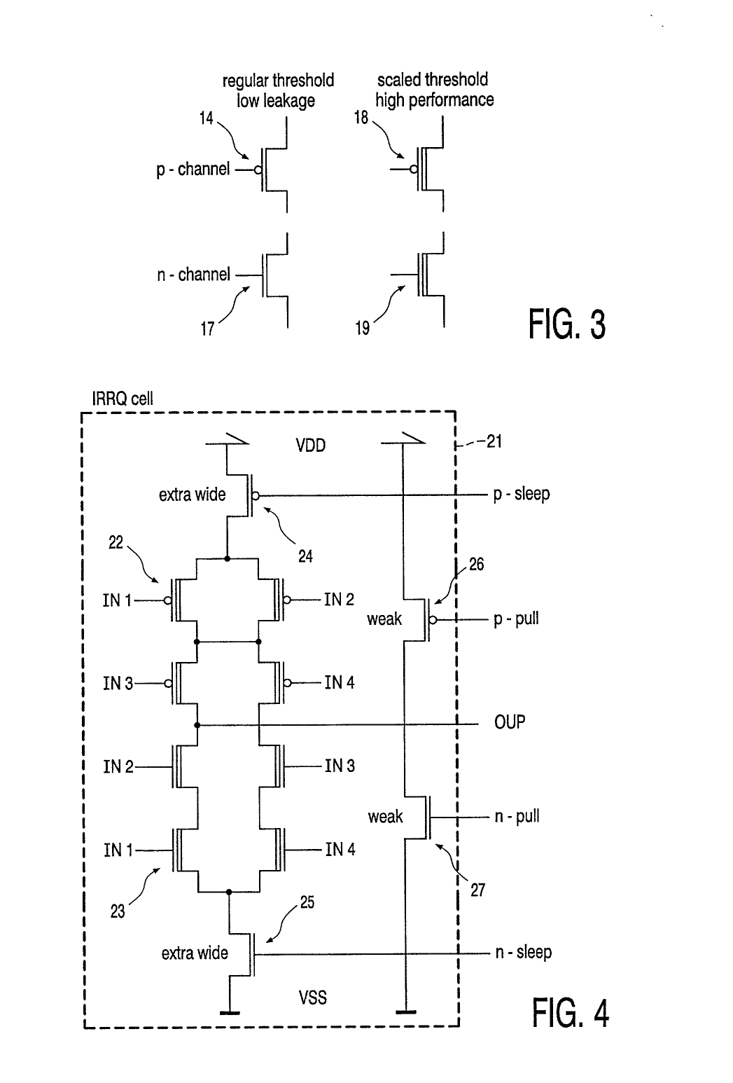

FIG. 3 explains the symbols used for four types of MOSFETs;

FIG. 4 shows an example of a logic gate with IRRQ facility having a subcircuit with sleep transistors on a per-cell basis;

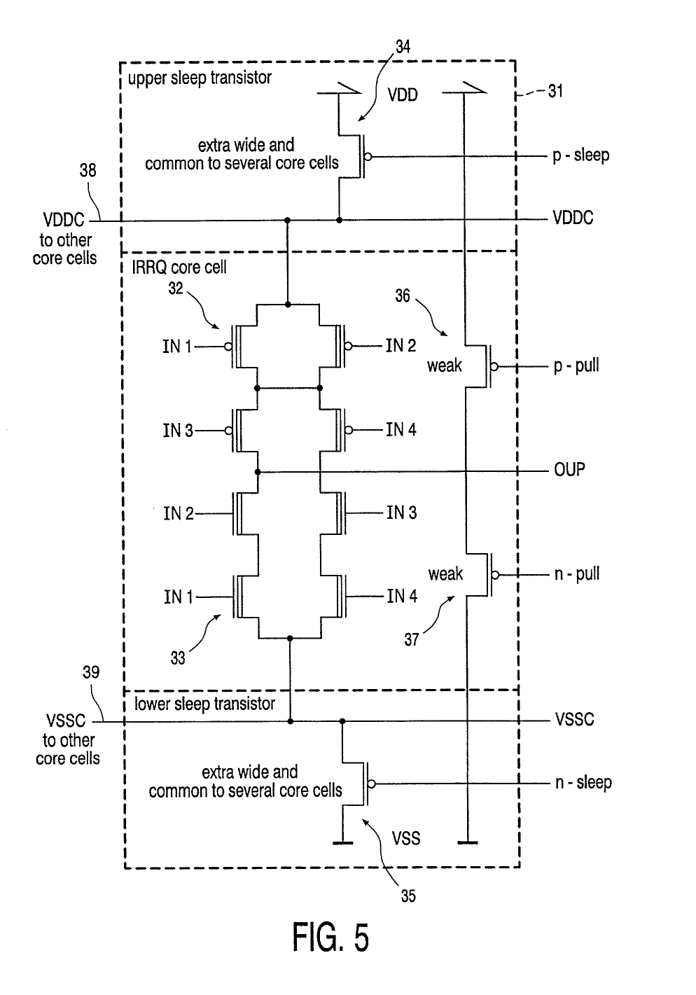

FIG. 5 illustrates an alternative circuit with sleep transistors shared between several logic gates; and

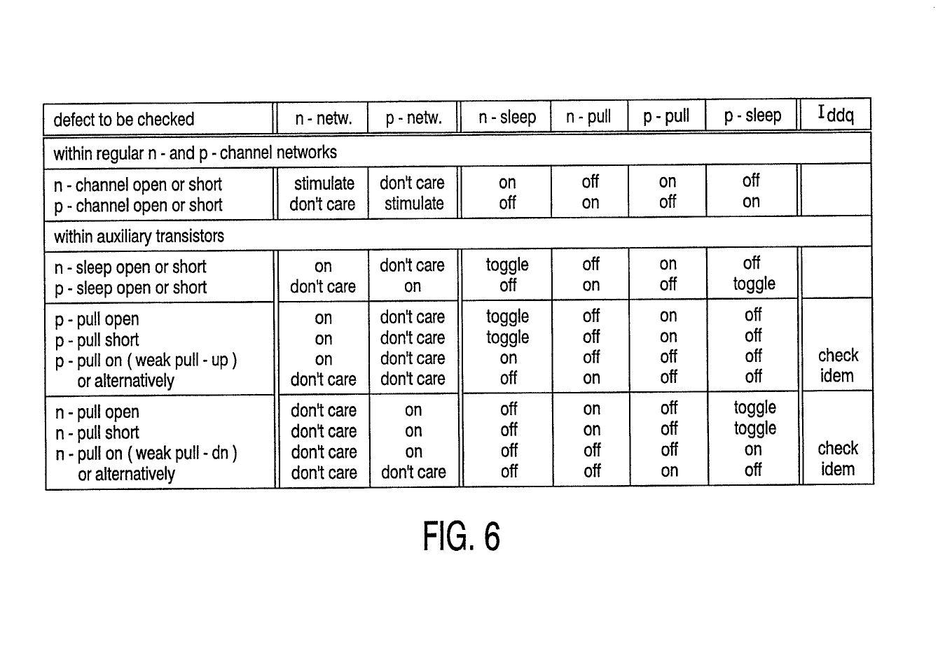

FIG. 6 shows a fault dictionary that lists the various potential fabrication defects in an IRRQ gate and that indicates how to drive the various transistors such as to uncover any given defect.

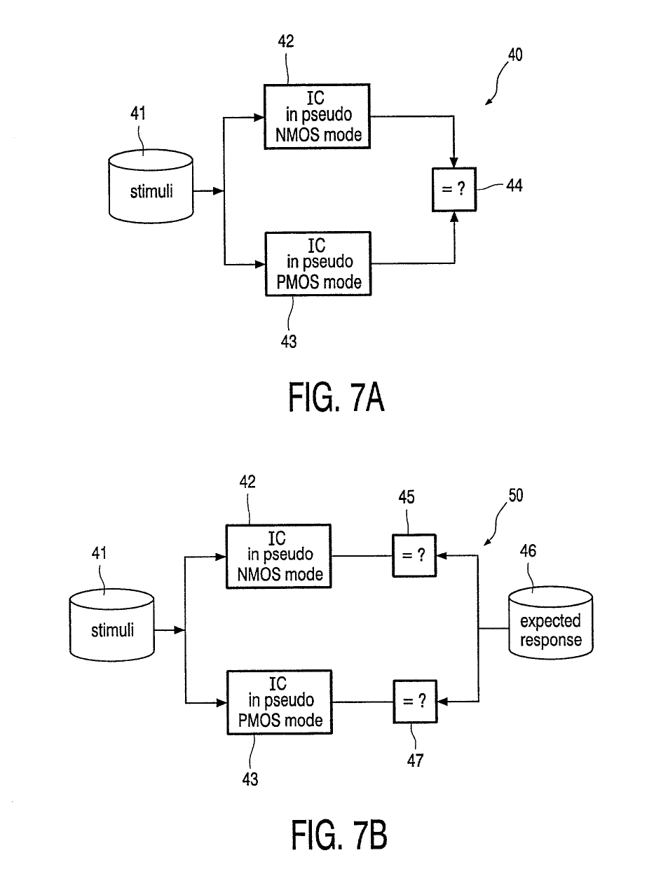

FIG. 7A is a schematic illustration of a first test mode, in accordance with the present invention.

FIG. 7B is a schematic illustration of a second test mode, in accordance with the present invention.

The digital circuit 1 of FIG. 1 is basically of standard type but it includes special features not found in ordinary gates. To implement IRRQ, each logic gate or circuit cell to be tested in this circuit can be thought of being replaced by an augmented subcircuit, according to the invention. Such a digital circuit 1 may comprise electronic elements 2, 3, 4 and 5, according to FIG. 1, which are self-explanatory. Said elements are in general transistor networks.

The arrangement 11 of FIG. 2 comprises an IRRQ cell provided with a circuit consisting of a p-channel pull-up network 12 and an n-channel pull-down network 13. The network 12 is connected via a p-sleep-transistor 14 to a first voltage source V_{DD} and the network 13 is connected via an n-sleep transistor 15 to a second voltage source Vₛₛ or to ground. Said sleep transistors 14, 15 also reduce the power while in standby mode. It is known in the art to employ one or two sleep transistors in order to put a circuit cell into a sleep-mode. The networks 12 and 13 are connected to an output OUP. The IRRQ arrangement comprises an additional p-pull transistor 16 connected between the output OUP and the voltage source V_{DD} and an additional n-pull transistor 17 connected between said output and the voltage source V_{SS}. V_{DD} is a power node and V_{SS} is a ground node. I.e., four MOSFETs 14, 15, 16, 17 are used to test a logic gate with the new IRRQ method. The other connections of this arrangement are apparent from FIG. 1.

According to FIG. 3 the transistors 14 and 17 are operated at a regular threshold voltage and have a low leakage current and the transistors 18 and 19 have a scaled, that is a lower, threshold and high performance. The transistors 14 and 18 have a p-channel and the transistors 17 and 19 an n-channel. Whether the unscaled and scaled threshold MOSFETs are being manufactured as such, or whether they are obtained electrically after fabrication, e.g., by way of back-biasing the body electrode, of overdriving the regular gate electrode, or of precharging a separate floating gate, is irrelevant.

For normal IC operation both sleep transistors 14 and 15 (FIG. 2) are turned on and both pull transistors 16, 17 are off, and the logic gate functions just as any regular static CMOS gate.

In the standby mode (sleep mode) the logic transistors are being electrically disconnected from the ground and supply rails by turning the sleep transistors 14, 15 off. As shown in FIG. 2, disabling either one of them actually suffices to cut the leakage path, and clearly the pull transistors 16 and 17 are shut off as well.

Checking a circuit's integrity is similar to conventional IDDQ testing, except that no IDDQ monitoring takes place and that a test takes two passes instead of one. For checking e.g. the n-channel network 13 first, the n-type sleep transistor 15 and the p-type pull transistor 16 are turned “on”, and the remaining two auxiliary MOSFETs 14 and 17 “off”. The gate now essentially operates like an NMOS gate (pseudo NMOS). The circuit 11 is being stimulated with a series of successive test vectors (stimuli) and the responses from the circuit 11 are being compared against the expected ones. Whether this happens off-chip with automatic test equipment (ATE) or on-chip with the aid of built-in self-test (BIST) circuitry is immaterial. Any defect in the n-channel pull-down network 13 results in a wrong response, provided the test vector set is made to cover that fault, that is to stimulate it from the inputs and to propagate the erroneous response to an observable output, or to an on-chip response analyzer.

In preparation of the second pass, all four auxiliary transistors 14-17 are switched so that the p-type sleep transistor 14 and the n-type pull transistor 17 are “on” and the other two transistors 15 and 16 “off” such as to make the gate function like a PMOS gate (pseudo PMOS). The entire operation is then repeated with the same set of vectors as before to check the p-channel pull-up network 12.

Similarly to IDDQ testing, IRRQ functions even when no expected responses are available to compare with. This is because the two complementary IRRQ passes must yield the same sequence of actual responses. If not so, one or both of the two networks 12, 13 have been found to be faulty.

FIG. 4 shows a logic gate 21 of the type AOI22 (AOI22 stands for a certain AND-OR-INVERT function) in IRRQ circuit style consisting of a p-channel network 22 and an n-channel network 23. The network 22 is connected to an extra wide p-sleep transistor 24 and the network 23 to an extra wide n-sleep transistor 25, wherein said transistors 24, 25 control only the IRRQ cell, what is here referred to as a logic gate 21 with a pair of sleep transistors on a per-cell basis. The alternative FIG. 5 illustrates a logic gate 31 with an IRRQ core cell 32, 33 connected between a V_{DDC} line 38 and a V_{SSC} line 39, so that further IRRQ core cells may similarly be connected to said lines, and one (V_{DDC}) of said lines is connected to a p-sleep transistor 34 and the other line (V_{SSC}) is connected to an n-sleep transistor 35. V_{DDC} is a power node common to a set of cells and V_{SSC} is a ground node common to a set of cells. Said lines are in general connection means for said extra wide transistors 34, 35 which are accordingly common to several core cells. The gates of FIG. 4 and 5 comprise also p-pull and n-pull transistors 26, 27 and 36, 37, respectively.

Accordingly, a pair of sleep transistors 14, 15 need not necessarily be included in every single cell as it is also possible to assign one pair to a row of standard cells, to a major functional block, e.g. as dedicated switches built from BJTs, or even to an entire IC, e.g., as part of the padframe 6. For example, one pair of sleep transistors may be assigned to a row of standard cells as special row end cells or hidden underneath ground and power lines and running the entire cell row in the layout. The nominal number of auxiliary transistors is so reduced from 4 g to 2+2 g where g stands for the number of gates. Yet, in order to handle the accumulated switching currents without unacceptable loss of performance, the collective sleep transistors need to be sized wider than sleep transistors on per cell-basis. According to FIG. 2, the capacitances of the V_{SSC} and V_{DDC} nodes act as helpful bypass capacitors in this case.

While both stuck-open and shorts of the pull transistors are easily detected during the testing procedures described above, pure logic testing may not always suffice to uncover stuck-on faults in the n- or p-pull transistors that might result from their gate electrode being stuck-at-1 or -0 respectively. A pair of tests that monitors the overall IDDQ solves the problem, but either one of the two sleep transistors must be turned off during that test to prevent any leakage path through the logic networks.

The new IRRQ circuit may be modified such as to make it possible to decompose the circuit into two simultaneous NMOS and PMOS networks for testing purposes, e.g. by adding a transmission gate or a pass transistor, or some other controlled switch between the n- and p-networks or by relocating the sleep transistors here. An example of such a circuit 40 is illustrated in FIG. 7A. The circuit 40 must then be complemented further with on-chip logic 44 on the basis of equi- or antivalence gates to compare the responses from the two complementary subcircuits 42 and 43 and to detect any disagreement. In conjunction with off-chip ATE, one might do with a single pass that exercises and verifies the correct operation of the two complementary networks 42, 43 at a time when applying stimuli 41. Additional outputs may be required.

Concurrent NMOS and PMOS evaluation can be used to support BIST (built-in self test) and/or self-monitoring during circuit operation. Sequential on-chip NMOS and PMOS evaluation can be done, e.g., using a setup as illustrated in FIG. 7A, using signature analysis. Signature analysis is a class of procedures where a long sequences of data are compressed to a shorter sequence (called signature), and where the various signatures are compared.

One might also consider operating an IRRQ gate as a dynamic CMOS circuit with subsequent precharge and evaluate phases rather than as a static NMOS/PMOS circuit while in test mode.

Leakage suppression and data retention are conflicting goals as any flip-flop or latch looses its current state whenever one or both of the sleep transistors are being turned off. Actual data losses are avoided by exempting all bistable feedback loops that store critical information from being powered down while the circuit is in standby, yet this inflates the residual leakage current. By carefully designing a circuit's power-down and -up procedures, much of its state information can be rendered uncritical, however, thereby reducing the number of leakage paths. Just consider pipeline registers and the master latches of master-slave flip-flops, for instance. Though none of this is specific to IRRQ, IRRQ is compatible with this practice.

The fault dictionary according to FIG. 6 indicates how to drive the n-sleep, n-pull, p-pull and p-sleep transistors to check defects within the n- and p-channel networks and within the auxiliary transistors.

As opposed to CMOS, both NMOS and PMOS circuits do dissipate static power which raises the question whether the extra heat generated during IRRQ testing forbids the idea of temporarily operating a CMOS circuit in pseudo NMOS and PMOS mode or not. According to an approximation the overall power dissipation of NMOS and PMOS circuits in accordance with the present invention is not expected to pose any problems.

It will be appreciated that the system according to the invention has a number of advantages. In particular, this system permits an integrity check of regular p- and n-channel networks in spite of leaky logic transistors, wherein auxiliary transistors are fully testable as well. The system works with zero or close to zero leakage currents in standby mode and without need to wait until transient currents have fully died out as with IDDQ. According to this system, also better fault coverage per functional/stuck-at vector, or same coverage with less vectors, can be obtained and controllability of internal nodes may be improved by driving pull transistors selectively. This system has no need for supply partitioning, back biasing or low temperature operation during tests.

Said advantages more than compensate for the need of two, three, or four extra transistors per logic gate, for the performance losses due to extra series resistance and load capacitance. Additional minor disadvantages of this system, whose logic circuitry may become ratioed and drains static current while in test mode and has possibly a reduced operating speed while in test mode, are indeed less relevant.

According to the present invention the detection of a defect in a circuit 40 is based upon an inconsistency between either of said two sequences of actual responses (as illustrated in FIG. 7A), or the detection of a defect in a circuit 50 is based upon an inconsistency between said sequences of actual responses and sequences of expected responses 46 (as illustrated in FIG. 7B). The term “expected responses” refers to a sequence of responses produced by a, possibly hypothetical, circuit (not illustrated in FIG. 7B) that is free of fabrication defects. The IRRQ testing even functions when no expected responses are available to compare with, as illustrated in FIG. 7A. This is because the two complementary IRRQ passes must yield the same sequence of actual responses. If not so, the circuit 44 will detect that one or both network 42, 43 is faulty. As illustrated in FIG. 7B, the circuits 45 and 47 compare the sequences of actual responses and sequences of expected responses provided by the circuit 46.

A preferred embodiment of the invention includes one or more of the following features:

Operating a digital CMOS circuit as pseudo NMOS and/or as pseudo PMOS circuit for the purpose of fabrication testing;

combining both leakage power reduction and fabrication test into one common circuitry;

using sleep transistors as dual function devices;

taking advantage of the redundancy inherent in static CMOS circuits on a logic level rather than electrically as is the case with IDDQ testing;

adding on-chip circuitry to support consistency checking between the n- and p-channel transistor networks;

detecting stuck-on faults in the pull transistors by way of standard IDDQ testing;

putting the pull transistors, and possibly the sleep transistors as well, to service for controlling inputs to downstream logic; and

using the sleep transistors to cut leakage paths.

In the drawings and specification there has been set forth preferred embodiments of the invention and, although specific terms are used, the description thus given uses terminology in a generic and descriptive sense only and not for purposes of limitation.

1. A method for testing integrated circuits having a plurality of field-effect transistors (FETs) of low threshold voltages, comprising the following steps:
determining at least one circuit cell (12, 13; 22, 23; 32, 33) to be tested in said integrated circuit;
separating said circuit cell (12, 13; 22, 23; 32, 33) into two independent cell networks;
obtaining a first response sequence for the first (12; 22; 32) of said two independent cell networks;
obtaining a second response sequence for the second of (13; 23; 33) said two independent cell networks, and
processing the first response sequence and the second response sequence in order to detect a defect in said circuit cell.

2. The method according to claim 1, wherein the step of processing comprises a step of comparing the first response sequence with the second response sequence to detect an inconsistency.

3. The method according to claim 1, wherein the step of processing comprises a step of comparing the first response sequence and the second response sequence with a sequence of expected responses to detect an inconsistency.

4. The method according to claim 1, comprising:
powering up said circuit cell (CMOS or BiCMOS);
selecting p- (12; 22; 32) and n-channel (13; 23; 33) transistor networks in said circuit cell;
putting said circuit cell (CMOS or BiCMOS) into a test mode whereby the p- and n-channel transistor networks in said circuit cell are stimulated by a sequence of test vectors;
obtaining a sequence of actual responses from said p-channel transistor network;
obtaining a sequence of actual responses from said n-channel transistor network;
determining whether a defect is detected in said circuit cell, wherein said step of detection is either based upon an inconsistency between said two sequences of actual responses or upon an inconsistency between said two sequences of actual responses and a sequence of expected responses.

5. The method of claim 1 or 4, wherein means (14, 15; 24, 25; 34, 35) are used to electrically separate said circuit cell into the first (12; 22; 32) of said two independent cell networks and the second (13; 23; 33) of said two independent cell networks.

6. The method of one of the claims 1 to 5, wherein load means (16, 17; 26, 27; 36, 37) are used which act as loads for said two independent cell networks (12, 13; 22, 23; 32, 33) while at least said cell of the integrated circuit to be tested is in test mode.

7. The method of claim 6, further comprising:
measuring the current drain of the circuit cell;
determining whether a defect is detected in said load means wherein said step of detection is based upon the amount of said current drain when said circuit cell has reached a predetermined quiescent state.

8. The method of one of the claims 4 to 7, comprising the additional step:
suppressing leakage currents in said circuit cell by turning off one or more of said control means while said circuit cell is in standby mode.

9. Integrated circuit including testing circuitry, comprising at least one circuit cell (12, 13; 22, 23; 32, 33), means (14, 15; 24, 25; 34, 35) to electrically separate said circuit cell into a first cell network (12; 22; 32) and a second cell network (13; 23; 33), and at least one output giving a first response sequence for the first of said two independent cell networks and a second response sequence for the second of said two independent cell networks.

10. The integrated circuit of claim 9, wherein the first cell network is a p-channel transistor network (12) and the second cell network is an n-channel transistor network (13).

11. The integrated circuit of claim 9 or 10, comprising control circuitry (14, 15; 24, 25; 34, 35) to deactivate said p- and n-channel transistor networks (12, 13; 22, 23; 32, 33) or to electrically separate them from each other, and wherein said control circuitry is connected in series with said n- and p-channel transistor networks.

12. The integrated circuit of claim 10 or 11, further comprising load means (16, 17; 26, 27; 36, 37) which act as loads for said p- and n-channel transistor networks while said network (12, 13; 22, 23; 32, 33) is in test mode.

13. The integrated circuit of one of the claims 10, 11, or 12, comprising connection circuitry (38, 39) connecting electrical signals of the control circuitry (34, 35) to other subcircuits for the purpose of testing them by selectively turning on or off said control circuitry and/or said load means (36, 37).
